(19) United States
(12) Patent Application Publication
(10) Pub. No.: US 2011/0020753 A1
(43) Pub. Date: Jan. 27, 2011

(54) Method for reversing tone of patterns on integrated circuit and patterning sub-lithography trenches

(75) Inventors: Lawrence A. Clevenger, Armonk, NY (US); Maxime Darnon, Armonk, NY (US); Anthony D. Lisi, Armonk, NY (US); Satya V. Nitta, Armonk, NY (US)

Correspondence Address: THE LAW OFFICES OF ROBERT J. EICHELBURG, HODAFEL BUILDING, SUITE 200, 196 ACTON ROAD, ANNAPOLIS, MD, 21403, US

(73) Assignee: International Business Machines Corporation, Armonk, NY (US)

(21) Appl. No.: 12/510,001

(22) Filed: Jul. 27, 2009

(51) Int. Cl. G03F 7/20

(52) U.S. Cl. 430/313

(57) ABSTRACT

A method for reversing the tone of a lithographic image on a substrate comprises depositing a modifiable material on a substrate; applying a photolithographic material on the modifiable material: defining a removable patterned area in the photolithopgraphic material by photolithograpic means; removing the patterned area to produce an exposed region in the modifiable material that substantially conforms to the patterned area; producing a reacted modifiable material by increasing the etch resistance of the modifable material substantially throughout the exposed region so that the etch resistance of the exposed region comprises a region that substantially conforms to the exposed region; and removing the photoresist and the modifiable material to leave the reacted modifiable material and substrate.

### FIELD OF THE INVENTION

The field of the invention comprises a method to reverse the tone of patterns and a method to define sub-lithographic trenches for Very Large Scale Integrated (VLSI) and Ultra-Large Scale Integrated (ULSI) devices.

### BACKGROUND OF THE INVENTION AND RELATED ART

The related art describes several techniques for reversing the tone of a pattern in microelectronics technologies. Most of these methods, however, suffer from several drawbacks including process control, materials stability during the process and an increase in the number of costly steps. These drawbacks result in very difficult integration of the processes.

For example, one methodology for reversing the tone of a pattern is to coat a planarizing layer on top of patterns defined by lithography, followed by by chemical mechanical polishing or by etching to remove the excess of planarizing material down to the top of the first patterns, and selectively removing the first patterns, leading to negative patterns on the top of the substrate. Slayman, et al. U.S. Pat. No. 4,973,544 discuss this; however, it is very difficult to stabilize the planarizing layer in this process without degrading the patterns created by the lithography.

Another way to reverse the patterns is to use so-called “nanoimprint” technologies. In this case, the patterns are defined in a mold, which is imprinted in a resist layer on the top of the substrate. The resulting patterns are reversed compared to the initial patterns. Such a technology, however, is not mature enough yet to be used in Very Large Scale Integrated (VLSI) and Ultra-Large Scale Integrated (ULSI) devices technologies.

Thus, there is a need for a simple and controllable method to reverse the tone of patterns on the top of a substrate in microelectronics technologies such as VLSI and ULSI processes.

Additionally, there is a constant need to create sub-lithographic patterns in microelectronics, in order to improve the devices performance and/or to compensate for the lack of resolution of lithography in VLSI and ULSI processes.

Several ways are available today to define sub-lithographic features. For example, the dimensions of lines can be shrunk by using isotropic etching (trimming process). Decreasing the width of trenches is more difficult. This can be done by depositing a liner on the patterns sidewalls (see, Sabnis et al., U.S. Pat. No. 7,122,296) or by forming a spacer on the patterns sidewalls (see, Lin, U.S. Pat. No. 5,863,707 and Pogge, U.S. Pat. No. 4,256,514). However, this necessitates the use of a sacrificial layer, and good process control.

Slayman et al., U.S. Pat. No. 4,973,544 disclose a method for reversing tone or polarity of a pattern on an integrated circuit substrate by means of reverse casting planarization. The reference describes forming a liquid planarizing layer hardened onto a patterned layer and underlying substrate followed by filling in spaces between patterned areas. The planarizing layer is then etched to a sufficient depth to expose the patterned layer, after which the patterned layer is dissolved away leaving a reversed tone image. This is made up of the planarizing material in the spaces that were filled in.

Another way to pattern sub-lithography patterns is the deposition of thick sidewalls polymers during the plasma etching. This technique leads to tapered profiles and to the presence of polymers on the sidewalls which can be responsible for yield loss.

Thus, there is a need for a simple and controllable method to pattern sub-lithographic trenches.

These needs are met by a process for reversing the tone of patterns employing the method of the present invention which uses a modifiable material.

### SUMMARY OF THE INVENTION

Accordingly, the present invention provides structures, articles of manufacture and processes that address these needs to not only provide advantages over the related art, but also to substantially obviate one or more of the foregoing and other limitations and disadvantages of the related art such as providing a simple and controllable method to pattern sub-lithographic trenches. Not only do the written description, claims, abstract of the disclosure, and the drawings that follow set forth various features, objectives, and advantages of the invention and how they may be realized and obtained, but these features, objectives, and advantages will also become apparent by practicing the invention.

To achieve these and other advantages, and in accordance with the purpose of the invention as embodied and broadly described herein, the invention comprises a method to reverse the tone of patterns by using a modifiable layer. Patterns are defined on top of a modifiable layer. The modifiable layer etching characteristics are changed in open areas, so that the unmodified material can be etched selectively toward the modified one, leading to inverted patterns. When the modification is isotropic, the dimensions of the patterns are shrunk by this process.

### BRIEF DESCRIPTION OF THE DRAWINGS

FIG. 1, comprising FIGS. 1a, 1b, and 1c illustrates a process flow of the present invention for reversing the tone of patterns.

FIG. 1a comprises a side elevation in cross section of a semiconductor device illustrating modifiable material deposition and lithography as part of the process flow of the present invention for reversing the tone of patterns.

FIG. 1b comprises a side elevation in cross section of a semiconductor device illustrating a modification process as part of the process flow of the present invention for reversing the tone of patterns.

FIG. 1c comprises a side elevation in cross section of a semiconductor device illustrating pattern transfer as part of the process flow of the present invention for reversing the tone of patterns.

FIG. 2, comprising FIGS. 2a, 2b, and 2c illustrates a process flow of the present invention in a further embodiment where sub-lithographic patterns are defined.

FIG. 2a comprises a side elevation in cross section of a semiconductor device showing modifiable material deposition and lithography to illustrate a process flow of another embodiment of the invention where sub-lithogpraphic patterns are defined.

FIG. 2b comprises a side elevation in cross section of a semiconductor device showing an isotropic modification process to illustrate a process flow of another embodiment of the invention where sub-lithogpraphic patterns are defined.

FIG. 2c comprises a side elevation in cross section of a semiconductor device showing a pattern transfer to illustrate a process flow of another embodiment of the invention where sub-lithogpraphic patterns are defined.

FIG. 3, comprising FIGS. 3a, 3b, 3c, and 3d illustrates a process flow of the present invention in a further embodiment where sub-lithographic patterns are defined.

FIG. 3a comprises a side elevation in cross section of a semiconductor device showing modifiable material deposition and lithography to illustrate a process flow of another embodiment of the invention where sub-lithogpraphic patterns are defined.

FIG. 3b comprises a side elevation in cross section of a semiconductor device showing pattern dimension shrinking to illustrate a process flow of another embodiment of the invention where sub-lithogpraphic patterns are defined.

FIG. 3c comprises a side elevation in cross section of a semiconductor device showing a modification process to illustrate a process flow of another embodiment of the invention where sub-lithogpraphic patterns are defined.

FIG. 3d comprises a side elevation in cross section of a semiconductor device showing a pattern transfer process to illustrate a process flow of another embodiment of the invention where sub-lithogpraphic patterns are defined.

### DETAILED DESCRIPTION

To achieve these and other advantages, and in accordance with the purpose of this invention as embodied and broadly described herein, the following detailed embodiments comprise disclosed examples that can be embodied in various forms.

The specific processes, compounds, compositions, and structural details set out herein not only comprise a basis for the claims and a basis for teaching one skilled in the art to employ the present invention in any novel and useful way, but also provide a description of how to make and use this invention.

The present invention comprises a method to reverse the tone of patterns in the field of microelectronics technologies. A conventional lithographic mask is used to define patterns on a modifiable layer.

Some embodiments of the invention comprise a method for reversing the tone of a lithographic image on a substrate by depositing a modifiable material on a substrate; applying a photolithopgraphic material on the modifiable material; defining a removable patterned area in the photolithopgraphic material by photolithograpic means; removing the patterned area to produce an exposed region in the modifiable material that substantially conforms to the patterned area; producing a reacted modifiable material by increasing the etch resistance of the modifable material in the exposed region so that the etch resistance of the exposed region comprises a region that substantially conforms to the exposed region; and removing the photoresist and the modifiable material to leave the reacted modifiable material and substrate.

In other embodiments at least one material is deposited before lithography that functions as at least one of an antireflective layer or a mask, wherein the antireflective layer or mask or both are etched before the modification process. The modifiable material may also comprise an anti reflective coating, and the dimensions of the patterns defined by lithography may be shrunk by isotropic etching which can be used to produce final patterns that are sub-lithographic.

In further embodiments the modifiable material can be oxidized and can comprise a material selected from one of Si, SiN, Ti, TiN, Ta, TaN, Ge, SiGe, BN, and combinations thereof. Furthermore, the modification process can also be used to remove the photoresist. In other embodiments, the modification process comprises an oxygen-based plasma oxidation, thermal baking, ultra violet radiation exposure, or ion implantation.

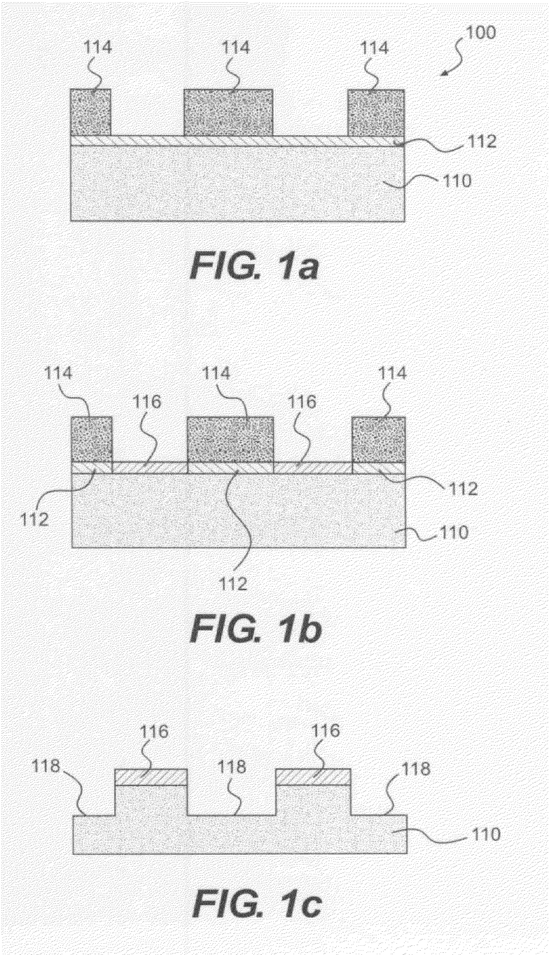

A process flow for the method of this invention is shown in FIG. 1. A semiconductor device 100 comprises a substrate 110 to pattern and a photoresist 114 pattern developed from a photoresist film (not shown). The substrate 110 is coated by a layer 112 of a material having etch characteristics which can be modified and which we describe as a modifiable layer. Different suitable materials and processes of modification will be proposed in the following. On this modifiable layer 112, patterns 114 are defined by lithography. The modifiable layer can eventually play the role of an anti reflective coating for the lithography. An additional mask layer (not shown in FIG. 1) can also be added between the modifiable layer 112 and a photoresist 114.

After lithography, a modification process is applied. The etch characteristics of the modifiable material which is not protected by the patterns are then modified which FIG. 1b shows as 116. The photoresist 114 is removed, leading to a flat surface where patterns are defined by the etch-characteristics of the modifiable layer. The unmodified material is then etched away, whereas the modified material 116 remains on the surface of the substrate. Thus, the surface presents patterns 118 which tone is reversed compared to the initial patterns.

The modifiable material comprises a material with characteristics that can be changed so that it will be etched slower than the unmodified material. The process of modification can be, but is not restricted to, a plasma process, a thermal treatment in a specific atmosphere (oxidizing or reducing), a UV exposure, and an ion implantation. This process can eventually be used to remove the photosresist at the same time. The modifiable material comprises at least one of Si, SiN, Ti, TiN, Ta, TaN, Ge, SiGe, or BN layers or other compounds or compositions and combinations thereof. The modification comprises oxidizing the silicon or silicon based material to form SiO₂ or oxidizing the foregoing metals or metal compounds with oxygen to form metal oxide modified materials or by using other oxidizing agents. The oidizing agent can be O₂, H₂O, O₃ or oxygen radicals or ions that from a plasma. The modification process also comprises nitridation such as in the case of germanium, where N₂ or NH₃ or nitrogen radicals or ions from a plasma can be used to form GeN as a modified material. The modification process also comprises ion implantation such as in the case of Si or Ge where B, P, As, Ga can be used for doping the material. The modification process also comprises reduction where reducing agents such as H₂ or H radicals can be used to reduce an oxide

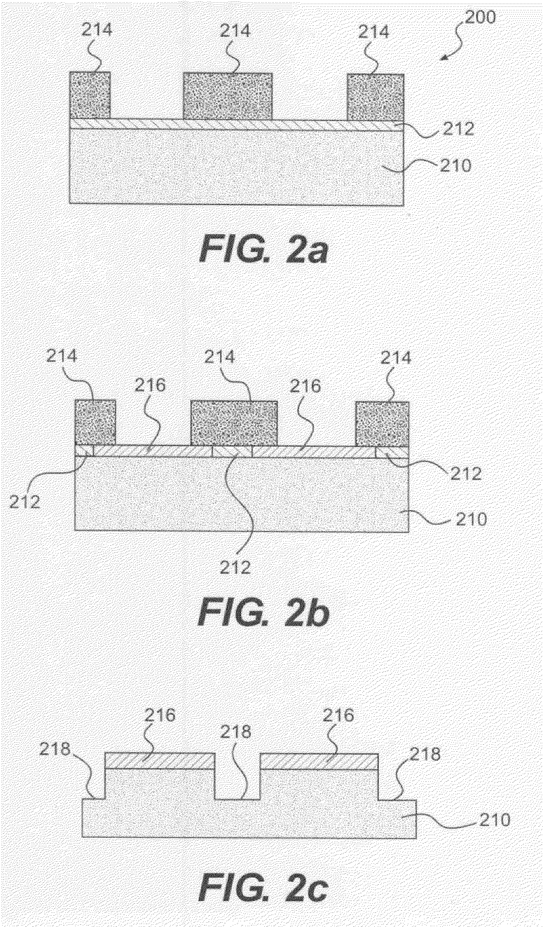

In another embodiment presented in FIG. 2, the modification of the modifiable layer is what we term “isotropic” for the purpose of the present invention. A process flow for the method of this aspect of the invention is shown in FIGS. 2a, 2b, and 2c, in which a semiconductor device 200 comprises a substrate 210 to pattern and a photoresist pattern 214 applied from a photoresist film (not shown). The substrate 210 is coated by a layer 212 of a material having etch characteristics which can be modified and which we describe in the discussion of FIG. 1 and comprises a modifiable layer. Different suitable materials for modification are substantially the same as described for FIG. 1. On this modifiable layer 212, patterns 214 are defined by lithography. The modifiable layer can eventually play the role of an anti reflective coating for the lithography. An additional mask layer (not shown in FIG. 2) can also be added between the modifiable layer 212 and a photoresist pattern 214.

After lithography, the modification process is applied as in the process employed in FIG. 1. The etch characteristics of the modifiable material which is not protected by the patterns are then modified which FIG. 2b shows as 216. The photoresist pattern 214 is removed, leading to a flat surface where patterns are defined by the etch-characteristics of the modified layer 216. The unmodified material 212 is then etched away, whereas the modified material 216 remains on the surface of the substrate. Thus, the surface presents patterns 216 which tone is reversed compared to the initial patterns. Importantly, we conduct this aspect of the process of the invention so that the modification of the material 212 extends under the patterns 214, on the sides of the open areas to form patterns 216. The final patterns 216 are then wider, leading to narrower trenches 218 having a width that can be sub-lithographic.

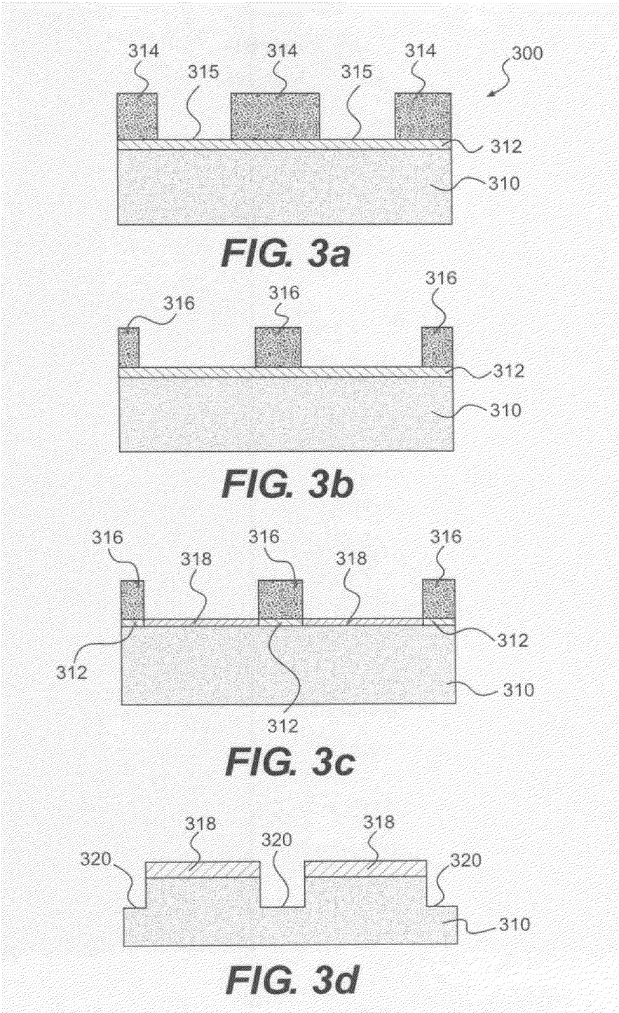

In another embodiment presented in FIG. 3, the dimensions of the first lithographic photoresist patterns 314 developed from a photoresist film (not shown) are shrunk using isotropic etching well known in the art (trimming process). A process flow for the method of this aspect of the invention is shown in FIGS. 3a. 3b, 3c, and 3d in which a semiconductor device 300 comprises a substrate 310 to pattern and photoresist patterns 314. The substrate 310 is coated by a layer 312 of a material having etch characteristics which can be modified and which we describe in the discussion of FIG. 1 and comprises a modifiable layer. Different suitable materials for modification are substantially the same as described for FIG. 1. On this modifiable layer 312, patterns 315 are defined by lithography. The modifiable layer can eventually play the role of an anti reflective coating for the lithography. An additional mask layer (not shown in FIG. 3) can also be added between the modifiable layer 312 and photoresist pattern 314. As previously noted in this aspect of the invention the dimensions of the first lithographic patterns 314 are shrunk using isotropic etching well known in the art (trimming process) in order to produce shrunken lithographic patterns 316.

After lithography and the aforementioned trimming process, a modification process is applied substantially in the same way as the modification process described above for FIG. 1. The etch characteristics of the modifiable material which is not protected by the patterns are then modified which FIG. 3c shows as 318. The photoresist (shrunken lithographic patterns) 316 is removed, leading to a flat surface where patterns 318 are defined by the etch-characteristics of the modifiable layer. Patterns 316 are then removed and the unmodified material 312 is then etched away, whereas patterns 318 comprising the modified material remain on the surface of the substrate. The surface presents new patterns or trenches 320 having a tone that is reversed compared to the initial patterns 314. The final patterns 318 are wider, leading to narrower trenches or patterns 320 having a width that can be sub-lithographic.

The method of the present invention is further illustrated by the following examples. If not set out in these examples, we use the following components, processes, elements, and equivalents to practice the invention they embody:
substrate: any material which needs to be etched, e.g., 300 mm silicon wafer; 300 mm silicon wafer coated by low-k dielectric; 300 mm silicon wafer coated with SiO_{2;}
antireflective coating: any antiflective coating known in the art, e.g., SiN, Brewer Science ARC® 91, Brewer Science ARC® 29SR, HEART004™;
resist layer: any photoresist layer known in the art, e.g., PAR710™, DHA1001™, PMMA, SU-8, Novolac;
standard lithography material can be projection, contact, nanoimprint, step and flash nanoimprint lithography material. The light sources for those lithographic methods can be G-line, I-line, DUV (248 nm, 193 nm, 157 nm, 126 nm, and EUV (13.4 nm) radiation sources;
CF₄-based plasma: E.g. capacitive plasma at 200 mTorr with 50 sccm CF₄/200 sccm Ar/800 W during 30 s, or Inductive plasma at 4 mTorr with 300 sccm CF₄/300 sccm CHF₃/500 W source 1100 W bias during 40 s;
Cl2 plasma: E.g: inductive plasma with 50 sccm Cl₂/100 sccm Ar/500 W source/100 W bias/20 s;
HF dip, e.g., 1% HF in water for 60″;
oxygen-based plasma, e.g., capacitive plasma at 200 mTorr with 50 sccm O₂/200 W during 30 s, or inductive plasma at 4 mTorr with 100 sccm O₂/500 W source during 40 s, or down stream plasma at 1 Torr with 500 sccm O₂/420 Ws at 250 degree C. during 60 s;
UV radiation (DUV, etc.), e.g., exposure to a UV source such as G-line, I-line, DUV (248 nm, 193 nm, 157 nm, 126 nm, and EUV (13.4 nm) radiation sources;

### Example 1

On a substrate, 40 nm of TiN is deposited by physical vapor deposition. A silicon-containing antireflective coating and a standard 193 or 248 nm resist layer are coated on the TiN layer. A standard lithography process is used to define 100 nm wide lines. The silicon-containing antireflective coating is etched using a CF₄-based plasma. Then, the photoresist is removed and the exposed TiN is oxidized by an oxygen-based plasma. Subsequently, the remaining silicon-containing antireflective coating is removed by a CF₄/O₂ plasma. Then, the TiN is etched by a Cl₂-based plasma. Since titanium oxide is not etched by Cl₂ plasmas, patterns remain where TiN was oxidized. Thus, 100 nm-wide trenches are defined in TiO₂ on the top of the substrate.

### Example 2

On a substrate, 30 nm of silicon is deposited. On this layer, 40 nm of silicon nitride is deposited. An antireflective coating and a standard 193 or 248 nm resist layer are coated on the SiN layer. A standard lithography process is used to define 100 nm wide lines. The antireflective coating and the SiN layer are etched using a CF₄-based plasma. Then, the photoresist is removed by an oxygen plasma. Subsequently, the substrate is baked in an oven at 1000 degree Celsius during 20 minutes in an O₂-rich ambient. The exposed silicon is thus oxidized, whereas the SiN prevents the oxidation of the protected silicon. Since the oxidation is based on oxygen diffusion, a lateral oxidation occurs under the SiN, leading to the formation of silicon oxide on the first 30 nm. After that, the silicon nitride is etched selectively toward SiO₂, and the silicon is etched by a Cl₂-plasma. Thus, 40 nm-wide trenches are defined in SiO₂ on the top of the substrate.

### Example 3

On a substrate, 100 nm of uncured SiCOH is deposited. An antireflective coating and a standard 193 or 248 nm resist layer are coated on the SiCOH layer. A standard lithography process is used to define 100 nm wide lines. Using an O₂-based plasma, the width of the line is reduced down to 50 nm. The antireflective coating is etched using a CF₄-based plasma. Then, the substrate is exposed to a UV radiation in order to crosslink the SiCOH polymer. The photoresist is then removed by an oxygen plasma. Using a 1:100 HF dip, the uncured SiCOH material is removed, whereas the part of the material exposed to UV radiation is not etched away. Thus, 50 nm-wide trenches are defined in SiCOH on the top of the substrate.

In addition to the foregoing, another aspect the invention comprises a method for reversing the tone of a lithographic image on a substrate comprising a) depositing a modifiable material on a substrate; b) applying a photolithopgraphic material on the modifiable material; c) defining a removable patterned area in the photolithographic material by photolithograpic means; d) removing the patterned area to produce an exposed region in the modifiable material that substantially conforms to the patterned area; e) producing a reacted modifiable material by increasing the etch resistance of the modifable material in the exposed region so that the etch resistance of the exposed region comprises a region that substantially conforms to the exposed region; and f); removing the photoresist and the modifiable material to leave the reacted modifiable material and substrate.

The foregoing method method may also comprises a) a process wherein at least one material is deposited before lithography that functions as at least one of an antireflective layer or a mask, wherein the antireflective layer or mask or both are etched before the modification process, b) the modifiable material also comprises an anti reflective coating, c) the dimensions of the patterns defined by lithography are shrunk by an isotropic etching, d) the modification process is isotropic, e) the final patterns are sub-lithographic f) the modifiable material can be oxidized, g) the modifiable material is selected from one of Si, SiN, Ti, TiN, Ta, TaN, Ge, SiGe, BN, and combinations thereof, h) the modification process is also used to remove the photoresist and may comprise i) an oxygen-based plasma, j) thermal baking, k) ultra violet radiation, l) or ion implantation, and any combination of the foregoing variations a) through l).

Throughout this specification, abstract of the disclosure, and in the drawings the inventors have set out equivalents, including without limitation, equivalent elements, materials, compounds, compositions, conditions, processes, structures and the like, and even though set out individually, also include combinations of these equivalents such as the two component, three component, or four component combinations, or more as well as combinations of such equivalent elements, materials, compositions conditions, processes, structures and the like in any ratios or in any manner.

Additionally, the various numerical ranges describing the invention as set forth throughout the specification also includes any combination of the lower ends of the ranges with the higher ends of the ranges, and any single numerical value, or any single numerical value that will reduce the scope of the lower limits of the range or the scope of the higher limits of the range, and also includes ranges falling within any of these ranges.

The terms “about,” “substantial,” or “substantially” as applied to any claim or any parameters herein, such as a numerical value, including values used to describe numerical ranges, means slight variations in the parameter. In another embodiment, the terms “about,” “substantial,” or “substantially,” when employed to define numerical parameter include, e.g., a variation up to five per-cent, ten per-cent, or 15 per-cent, or somewhat higher or lower than the upper limit of five per-cent, ten per-cent, or 15 per-cent. The term “up to” that defines numerical parameters means a lower limit comprising zero or a miniscule number, e.g., 0.001. The terms “about,” “substantial” and “substantially” also mean that which is largely or for the most part or entirely specified. The inventors also employ the terms “substantial,” “substantially,” and “about” in the same way as a person with ordinary skill in the art would understand them or employ them. The phrase “at least” means one or a combination of the elements, materials, compounds, or conditions, and the like specified herein, where “combination” is defined above. The terms “written description,” “specification,” “claims,” “drawings,” and “abstract” as used herein refer to the written description, specification, claims, drawings, and abstract of the disclosure as originally filed, or the written description, specification, claims, drawings, and abstract of the disclosure as subsequently amended, as the case may be.

All scientific journal articles and other articles, including internet sites, as well as issued and pending patents that this written description mentions including the references cited in such scientific journal articles and other articles, including internet sites, and such patents, are incorporated herein by reference in their entirety and for the purpose cited in this written description and for all other disclosures contained in such scientific journal articles and other articles, including internet sites as well as patents and the aforesaid references cited therein, as all or any one may bear on or apply in whole or in part, not only to the foregoing written description, but also the following claims, abstract of the disclosure, and appended drawings.

Although the inventors have described their invention by reference to some embodiments, other embodiments defined by the doctrine of equivalents are intended to be included as falling within the broad scope and spirit of the foregoing written description, and the following claims, abstract of the disclosure, and appended drawings.

We claim:

1. A method for reversing the tone of a lithographic image on a substrate comprising:
a) depositing a modifiable material on a substrate;
b) applying a photolithopgraphic material on said modifiable material;
c) defining a removable patterned area in said photolithographic material by photolithograpic means;
d) removing said patterned area to produce an exposed region in said modifiable material that substantially conforms to said patterned area;
e) producing a reacted modifiable material by increasing the etch resistance of said modifable material in said exposed region so that the etch resistance of said exposed region comprises a region that substantially conforms to said exposed region; and
f) removing said photoresist and said modifiable material to leave said reacted modifiable material and substrate.

2. The method of claim 1 where at least one material is deposited before lithography that functions as at least one of an antireflective layer or a mask, wherein said antireflective layer or mask or both are etched before the modification process.

3. The method of claim 1 where the modifiable material also comprises an anti reflective coating.

4. The method of claim 1 where the dimensions of the patterns defined by lithography are shrunk by an isotropic etching.

5. The method of claim 1 where the modification process is isotropic.

6. The method of claim 1 where the final patterns are sub-lithographic.

7. The method of claim 1 where the modifiable material can be oxidized.

8. The method of claim 1 where the modifiable material is selected from one of Si, SiN, Ti, TiN, Ta, TaN, Ge, SiGe, BN, and combinations thereof.

9. The method of claim 1 where the modification process is also used to remove the photoresist.

10. The method of claim 1 where the modification process comprises an oxygen-based plasma.

11. The method of claim 1 where the modification process comprises a thermal baking.

12. The method of claim 1 where the modification process comprises ultra violet radiation.

13. The method of claim 1 where the modification process comprises ion implantation.
